(19) United States
(12) Patent Application Publication
(10) Pub. No.: US 2002/0008464 A1
(43) Pub. Date: Jan. 24, 2002

(54) Woven or ink jet printed arrays for extreme UV and X-ray source and detector

(76) Inventor: Alton O. Christensen, Houston, TX (US)

Correspondence Address: William B. Patterson, THOMASON, MOSER & PATTERSON, L.L.P., Suite 1500, 3040 Post Oak Blvd., Houston, TX, 77056, US

(21) Appl. No.: 09/840,450

(22) Filed: Apr. 23, 2001

Related U.S. Application Data
(63) Continuation-in-part of application No. 09/823,269, filed on Mar. 30, 2001.
Application No. 09/823,269 is a continuation-in-part of application No. 09/218,233, filed on Dec. 22, 1998, now Pat. No. 6,229,259.

(51) Int. Cl. H05B 33/14

(52) U.S. Cl. 313/498

(57) ABSTRACT

Polymer photoconduction and photoemission devices and arrays for use in photoresist, two-way communication, identification and detection processes, and other products and photonic devices. The apparatus is functionally responsive to X-ray and EUV radiation. The apparatus is preferably embodied in an array which can both sense and emit UV radiation at around wavelengths λ=145 nm to λ 100 nm. The devices can be fabricated by forming woven polymer fibers or ink-jet printed polymers into an array or arrays. Each array can also be integrally fabricated with address and control circuitry required to obtain the desired functionality.

### CROSS-REFERENCE TO RELATED APPLICATIONS

This disclosure is a continuation-in-part of U.S. application Ser. No. 09/823,269, filed Mar. 30, 2001, which is a continuation-in-part of U.S. application Ser. No. 09/218,233, filed Dec. 22, 1998.

### BACKGROUND OF THE DISCLOSURE

1. Field of the Invention

This invention is directed toward polymer photoconduction and photoemission devices and arrays for use in photoresist exposure, two-way communication, identification and detection processes and other products and photonic devices. More specifically, the invention is directed toward programmable arrays which operate efficiently to produce and/or sense radiation with wavelength λ at about λ=150 nm to λ=100 nm in the extreme ultra violet (EUV) and X-ray region. Such arrays are fabricated by forming woven polymer fibers, or alternately by ink-jet printed polymers into an array or arrays, wherein each array comprises integrally fabricated address and control circuitry.

2. Description of the Related Art

U.S. Pat. Nos. 5,656,883 and 5,663,559, both to Alton O. Christensen, Sr. (Christensen) disclose true-ohmic contact structures for injecting charge into a vacuum interface, namely, field emission. U.S. Pat. No. 5,977,718, and U.S. patent application Ser. Nos. 09/218,233 and 09/823,269, all to Christensen, disclose other materials of a true-ohmic contact interface to inorganic, organic and polymer devices. More specifically, U.S. patent application Ser. No. 09/218,233 discloses woven polymer semiconductors and electroluminescent fibers comprising pixel components and control circuitry. Furthermore, U.S. patent application Ser. No. 09/823,269 discloses electroluminescent (EL) and other polymer structures suitable for fabrication by weaving and by printing.

The above references teach the principles, materials and means for providing true solid/solid interface Mott-Gurney, no-barrier, true-ohmic contact to n-type semiconducting inorganic and metal-organic compounds, polymers and co-polymers of band gaps greater than 1.6 electron Volt (eV) used in electronic circuitry, EL and other photonic devices. In summary, the references teach that when contact is made between an n-type semiconductor and a conductor whose work function is less than half the semiconductor band gap plus the electron affinity, charge exchange occurs to obtain equilibrium. In the charge exchange, interface traps are filled and the conduction band of the semiconductor is accumulated with electrons. The greater the positive difference, the greater charge exchange occurs to achieve equilibrium, filling some bulk traps as well. The net effect is to increase conductivity and electron mobility. These principles, materials and methods are utilized in the present invention, and the above cited U.S. patents and applications, are hereby entered into this application by reference.

The literature contains reference information related to the invention set forth in this disclosure. More specifically, the status of the prior art in electroluminescent (EL) polymer device design is well documented by the review article by R. H. Friend, et al. (Friend et al.), in “Electroluminescence in Conjugated Polymers,” NATURE, Vol.397, Jan. 14, 1999, page 121. K. J. Less and E. G. Wilson (Less et al.) in “Intrinsic Photoconduction and Photoemission in polyethylene”, J. Phys. C, Solid State Phys., Vol. 6, 1973, page 3110 provides the polyethylene data evaluated using a metal-high density polyethylene-metal diode. This data is incorporated in the present disclosure.

### SUMMARY OF THE INVENTION

This disclosure extends the cited above in triode electroluminescent devices, structure, arrays and materials. Apparatus and methods are extended to include to X-ray and EUV polymer photoconduction and photoemission devices and arrays for use in (a) exposure of photoresist, (b) two-way communication devices, (c) identification and detection processes and (d) other products and photonic devices.

The above cited references, which have been entered by reference, teach the principles, materials and means for providing true solid/solid interface Mott-Gurney, no-barrier, true-ohmic contact to (a) n-type semiconducting inorganic and metal-organic compounds and (b) polymers and co-polymers of band gaps greater than 1.6 electron Volts (eV) used in electronic circuitry, EL devices and other photonic devices. In summary, the teachings and effects are as follows:

(1) when contact is made between an n-type semiconductor and a conductor whose work function φₘ is less than half of (E_{g}/2+χ) where E_{g} is the semiconductor band gap and χ is the electron affinity, then charge exchange occurs to obtain equilibrium;

(2) in the charge exchange, interface traps are filled and the conduction band of the semiconductor is accumulated with electrons;

(3) the greater the positive difference between (E_{g}/2+χ=φₘ) and work function φₘ the greater charge exchange occurs to achieve equilibrium, filling some bulk traps as well; and

(4) the net effect is to increase conductivity, electron mobility and reduce space charge.

The above principles and materials are combined with new materials and methods to form the basis of the present disclosure. Polyethylene has n-type conductivity, a band gap of 8.8 eV, negative electron affinity χ=−1.2 eV, and photoconductive sensitivity is narrowly centered about 8.4 eV, or at a wavelength of about λ=147 nm in the extreme UV (hereinafter “EUV”) region. This region is beyond the range of sunlight UV detected on the earth's surface. High conductivity contacting metal CuCa₂ of work function of about 1.6 eV alloys with polyethylene and co-polymers of polyethylene at about 300 degrees Kelvin (° K) producing a true ohmic contact. Doping and co-polymerization of polyethylene of differing densities allow design of center wavelengths between 150 nm and 100 nm, differing from the prior art, and are employed in apparatus and methods of the present invention.

Method and means are disclosed for eliminating barrier contacts required in prior art diode devices. Examples of such diode devices are presented in the cited patents and applications. The barrier contacts reduced efficiency of both photoconduction and photoemission of the prior art diode devices. Photoconduction and photoemission are increased by the use of a triode array of organic junction field effect transistor (OJFET) devices, each having a surrounding gate that controls carrier energy and balance. True ohmic contacts inject carriers and fill interface and bulk traps, thereby increasing carrier mobility of the OJFET devices by a factor approaching 10⁵. These true ohmic contacts also increasing space-charge distance by a factor of 50 or more.

An OJFET is functionally a monocolor pixel, and is also functionally operable to sense radiation and, alternately, to emit radiation about a design of center wavelength between 150 nm and 100 nm. The pixel OJFET operates in a short-channel, normally OFF, gate-controlled mode. Pixels are also preferably operated in an array. For operation in a photoconduction and sensing mode, the devices of the array are biased near avalanche. Sensing a query, the illuminated part of the array will avalanche multiply the impinging radiation for detection and decoding. In transmitting a query or in responding to a recognized query, the array of pixels programmed with the intelligence or identity will cause the selected pixels to avalanche and thereby operating in an emission mode. Operating in this mode, the array efficiently emits an emission pattern at the design center wavelength between 150 nm and 100 nm. Basic information on OJFET and organic metal semiconductor field effect transistor (OMESFET) operation are included in standard texts such as M. E. Sze., “Physics of Semiconductor Devices”, second edition, (page 312).

The OJFET drain-to-source field has polymer-chain field orientation, rather than a diode cross-chain field. This orientation further improves sensing efficiency and radiative emission of the device by lowering non-radiative interchain reaction. The OJFET's surround gate enhances carrier balancing. Carrier balancing may be “tuned” for a particular polymer or co-polymer by the positioning of the gate relative to the source electrode. Arrays formed with a large number of elements enhance X-ray and EUV signals.

The OJFET gate electrode provides reduced cross talk. The OJFET gate electrode also increases the ease of addressing of individual array elements and array programming as compared to diode gate electrodes. Improved OMESFET array address, logic and control circuitry is disclosed in previously cited U.S. Patent Application Serial No. 09/823,269. This circuitry is integrally fabricated with the arrays for efficiency and economy of production.

### BRIEF DESCRIPTION OF THE DRAWINGS

So that the manner in which the above recited features, advantages and objects the present invention are obtained and can be understood in detail, more particular description of the invention, briefly summarized above, may be had by reference to the embodiments thereof which are illustrated in the appended drawings.

FIG. 1 is a partial cross-section schematic of the preferred OJFET element which is used in arrays;

FIG. 2 is a partial planar topology of a redundant array element OJFETs;

FIG. 3 is a partial planar view of direction of an ink-jet printing operation filling polyethylene areas in the fabrication of OJFETs and associated circuitry;

FIG. 4 is a cross-section of the preferred dynamic OMESFET logic inverter device;

FIG. 5 is a partial planar topology of a dynamic NOR-OMESFET logic element;

FIG. 6 is a partial cross-section of FIG. 5 NOR-OMESFET logic element;

FIG. 7 is a partial cross-section of the pixel element of FIG. 1 interconnection with overlying NOR-OMESFET of FIG. 6; and

FIG. 8 is a block diagram of array read/write/erase control system with an outboard computer controller and display.

### DETAIL DESCRIPTION OF THE PREFERRED EMBODIMENTS

This invention comprises triode electroluminescent polymer and co-polymer devices, structures, arrays and materials which are designed to transmit and receive radiation in the extreme. The triode devices are functional to radiation at its design center wavelength between 150 nm and 100 nm. More specifically, they can function as an emitter of radiation at its design center wavelength, or conversely, as a sensor of radiation at its design center wavelength. The triode are preferably configured in arrays and combined with programmable control systems to form photoconduction and photoemission apparatus for use in (a) exposure of photoresist in integrated circuit manufacture, (b) two-way communication devices, (c) identification and detection processes and (d) medical and other products and photonic devices.

The invention utilizes prior art and referenced principles, materials and means for providing true solid/solid interface Mott-Gurney, no-barrier, true-ohmic contact to (a) n-type semiconducting inorganic and metal-organic compounds and (b) polymers and co-polymers of band gaps greater than 1.6 eV. These principles and materials are combined with new materials and methods to form the basis of the present invention. Polyethylene is a key component of the invention, and has (a) n-type conductivity, (b) a band gap of 8.8 eV, (c) negative electron affinity χ=−1.2 eV and (d) photoconductive sensitivity is narrowly centered about 8.4 eV, or at a wavelength of λ=147 nm in the EUV region. This region is beyond the range of sunlight UV detected on the earth's surface, therefore devices and apparatus require no special shielding from sunlight. High conductivity contacting metal CuCa₂ of work function of about 1.6 eV alloys with polyethylene and co-polymers of polyethylene at about 300° K producing a true ohmic contact used in the invention. Doping and co-polymerization of polyethylene of differing densities allow design of center wavelengths between 150 nm and 100 nm, differing from the prior art, and are alternately are employed in apparatus and methods of the present invention.

Barrier contacts, required in prior art diode devices disclosed in the cited patents and applications, are not required in the present invention. These barrier contacts reduced efficiency of both photoconduction and photoemission of the prior art diode devices. Photoconduction and photoemission are increased by the use of a triode array of OJFET devices, each having a surrounding gate that controls carrier energy and balance. The true-ohmic contacts within the devices disclosed inject carriers and fill interface and bulk traps thereby increasing carrier mobility by a factor approaching 10⁵. In addition, space-charge distance is increased by a factor of 50 or more.

As stated previously, an OJFET is functionally a monocolor pixel. The OJFET pixel operates in a short-channel, normally OFF, gate-controlled mode. For operation in a photoconduction sensing UV mode, the devices of the array are biased near avalanche. For operation in a query-sensing mode, the illuminated part of the array will avalanche multiply the impinging UV photons for detection and decoding. In transmitting a query, or in responding to a recognized query, an array of pixels programmed with the intelligence or identity will cause the selected pixels to avalanche and thereby efficiently emit the pattern of UV photons. Basic operation principles of prior art OJFET and OMESFET devices are presented in the previously referenced publication by M. E. Sze., “Physics of Semiconductor Devices”, second edition, (page 312).

The OJFET drain-to-source field has polymer-chain field orientation, rather than a diode cross-chain field. This orientation further improves efficiency and radiative emission of the device by lowering non-radiative interchain reaction. The OJFET's surrounding gate enhances carrier balancing. Carrier balancing may be “tuned” for a particular polymer or co-polymer by the physical positioning of the gate relative to the source electrode as will be subsequently illustrated.

The apparatus of the present invention can be fabricated by weaving techniques disclosed in U.S. patent application Ser. No. 09/218,233, which has been entered into this application by reference. Alternately, the apparatus of the present invention can be fabricated by printing methods disclosed in U.S. patent application Ser. No. 09/823,269, which has been en application by reference. It should be understood of FIGS. 1, 2, 4, 5 and 6 detailed below illustrate structures that are fabricated in one embodiment as woven fibers, and in an alternative embodiment by ink-jet printed materials. In fabricating by weaving, fibers are first spun to be rectangular in cross-section of the individual widths and thickness designed for their respective portions of the device they produce. Those fibers are then loom-woven by a computer controlled loom, wherein the computer a stored program for each woven device. In fabricating by printing, a computer controlled printer (preferably an ink jet printer) is employed. A program stored within the computer directs and controls operation of the ink jet printer to fabricate a specific device. The thickness of woven semiconductor fibers is many times that of inkjet printed semiconductor area's thickness of about 100 nm. The greater volume of woven fiber EL semiconductors reflects in greater luminous output as compared to ink-jet printed EL semiconductors.

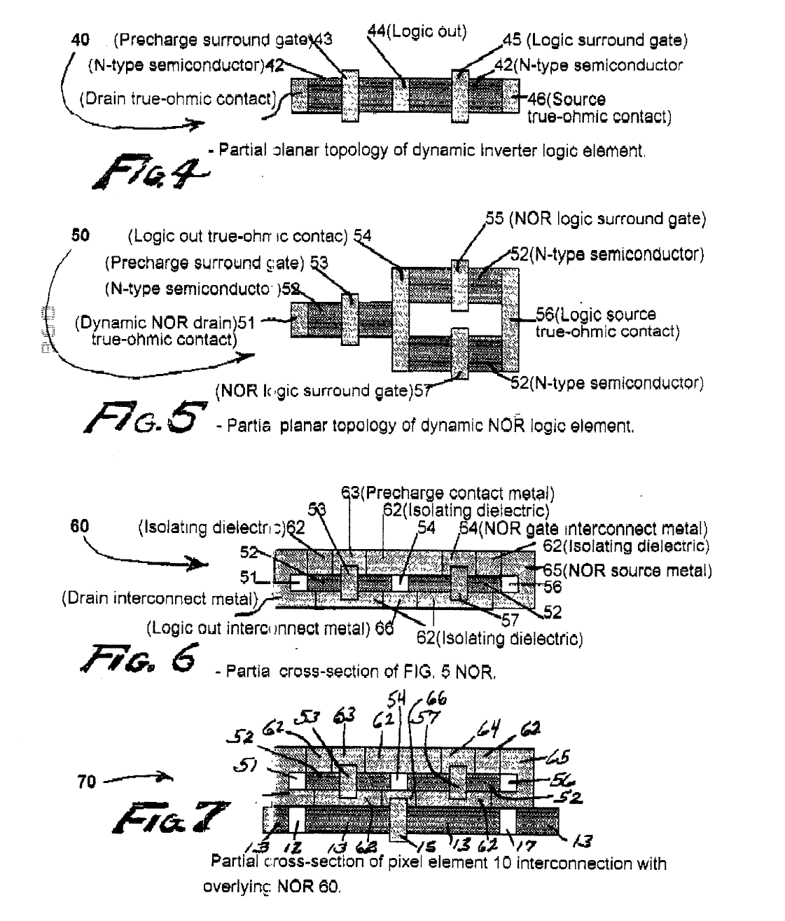

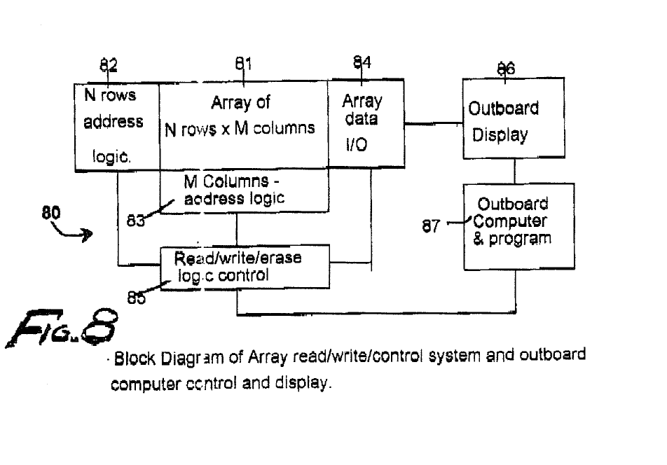

Attention is directed to FIG. 1 which is a partial section of the preferred embodiment OJFET structure employed as array elements. The structure is generally denoted by the numeral 10. The normally OFF OJFET device 10 consists of n-type polyethylene 13, having a source true ohmic contact metal CuCa₂ 12 contacting a source end of 13, and a drain true ohmic contact metal CuCa₂ 16 contacting a drain end of 13. A 2.5 eV to 3.5 eV band gap p-type polymer surround gate 15 contacts the polyethylene 13, and is carbon doped for high conductivity with a true ohmic connection by gold (Au) metal and interconnection metal CuCa₂ for source, drain and gate denoted by 11, 16 and 14, respectively. When the gate 15 is equidistant from source 12 and drain 17, the distances designated 18 and 19 are equal and about 2000 nm each. Gate 15 may be adjusted to be closer to or further from source contact 12 for current balancing. In that instance neither 18 nor 19 should exceed 2000 nm, to eliminate space-charge current limitation. OJFET device 10 is operated in the normally OFF mode. Source interconnect metal 11 is normally connected to system ground potential. Gate interconnect metal 14 is operated at a negative potential relative to the source interconnect metal 11. The drain interconnecting metal 16 is operated at a positive potential relative to that of 11 and 14, and is supplied by address and control logic circuitry as partially illustrated in FIG. 6.

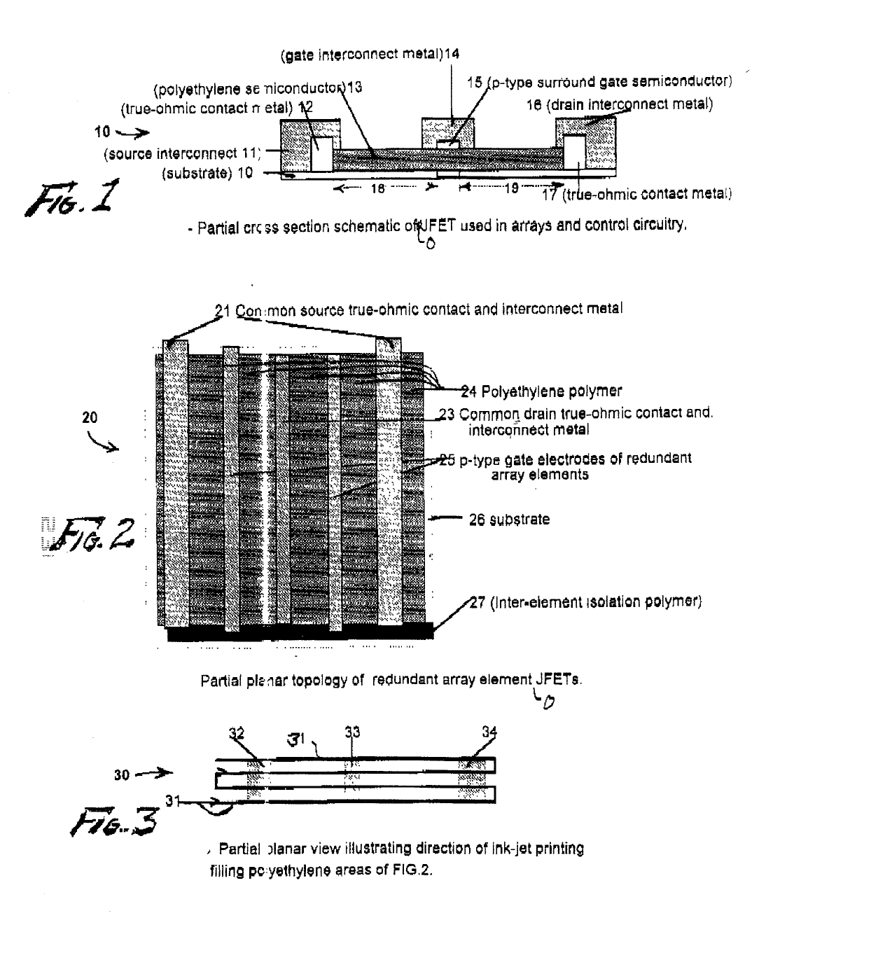

FIG. 2 is a planar topology of a pixel comprised of redundant pixel element normally OFF OJFETs. The structure is denoted as a whole by the numeral 20, with alternative embodiments either as ink-jet printed or as woven fibers. The structure is fabricated upon a radiation absorbing substrate 26 and coated with an oxygen barrier, which is not shown for clarity. The planar view reflects the cross-section of FIG. 1. The EUV polymer 24 is polyethylene. The common source true ohmic contact and overlying interconnect metal 21 is shared by the pixel element pairs. Adjoining lateral pixels (not shown for clarity) are replicas of 20. More specifically, a first lateral pixel shares the right-hand source 21 and a second lateral pixel shares the left-hand 21. Additional pixels 20 can be extended above and below making common connection with source metal pairs 21. All source metal 21 is normally at system ground. The added pixels of a desired aggregate area altogether comprise the pixels of a display. The gate ohmic contacts and overlying interconnect metal 22, and the common pixel drain ohmic contact (not shown in this view) and overlying connecting metal 23, provide connection to overlying color address and logic devices of FIGS. 4, 5 and 6 as illustrated in FIG. 7.

Attention is now directed to FIG. 3, which is a partial and conceptual planar view of device fabrication using ink-jet printing. Fabrication comprising the writing of successive and contiguous lines 31 of semiconductor essentially parallel to the source-to-drain field, which is defined as the region between source element 32 drain element and 34. Again, this is a conceptual representation of all pixel elements and control circuit device semiconductors. When a field is applied, the probability of cross-chain carrier migration is reduced since the polymer chains are essentially printed in parallel with that field. As a result, the along-chain carrier luminous output probability increased. The element 33 represents device gates. Elements of the device are printed in a pattern and in a sequence necessary to fabricate the device as disclosed. The printing apparatus is controlled by a computer that is programmed to generate the desired pattern and sequence.

FIG. 4 is a partial planar topology of the preferred embodiment, dynamic OMESFET inverter logic device, generally indicated by the numeral 40. Device 40 has a drain true-ohmic contact 41 of CuCa₂ to n-type semiconductor 42 of band gap greater than 2.6 eV, a high barrier surrounding gate metal 43 of Au, a logic output true ohmic contact 44 of CuCa₂, a high barrier surrounding logic gate 45 of Au, and a source true-ohmic contact metal 46 of CuCa₂.

Attention is next directed to FIG. 5, which is a partial planar view of the preferred embodiment of NOR implementation of the dynamic OMESFET of FIG. 4, and which is generally indicated by the numeral 50. NOR 50 has a true-ohmic contact drain 51 of CuCa₂ to n-type semiconductor 52 of band gap greater than 2.6 eV, a high barrier surrounding precharge gate 53 of Au, logic output true ohmic contact 54 of CuCa₂, a high barrier surrounding logic input gates 55 and 57 of Au and a source true-ohmic contact metal 56 of CuCa₂.

FIG. 6 is a partial cross-section of the NOR shown in FIG. 5, and is generally indicated by the numeral 60. The NOR 60 has drain interconnect 61, precharge gate interconnect metal 63 of CuCa₂, NOR gates interconnect metals 64 of CuCa₂, NOR source interconnect metal 65 of CuCa₂, and logic out interconnect metal 66 of CuCa₂. The use of CuCa₂ as interconnect metal is unique. Ca₂ in combination with Cu serves to limit both the diffusion and electromigration of Cu, thereby increasing long-term reliability of interconnections. There are five areas of dielectric isolation 62 indicated. If the device is fabricated by ink jet printing, each isolation area 62 would be separately ink-jet printed of one of the many silica-based low dielectric constant materials available commercially. Alternately, if the device 60 is fabricated by weaving, each of the five 62 areas indicated in cross-section are Teflon® fiber (k=2) both for dielectric isolation and to assume the tension of the warp or woof of the loom.

FIG. 7 is a partial cross-section of a pixel element 10 (see FIG. 1) integrated and interconnected with an overlying NOR 60 (see FIG. 6). The combination is generally indicated by the numeral 70, and details of each sub element are given in their respective description above.

Attention is next directed to FIG. 8, which is a block diagram of an array read/write control system and outboard computer control and display. The combination device is generally indicated by the numeral 80. The heart of the system 80 is an N by M array 81 of the OJFETs illustrated in FIGS. 1 and 2. The array 81 N rows are addressed by logic elements 82, as illustrated in FIG. 6, which is integrated with the array 81. The M columns of array 81 are addressed by logic elements 83, which are illustrated in FIG. 6 and which are integrated with array 81 in FIG. 8. The N row and M column address logics are controlled by 85, which is a read/write/erase control logic. The logic functions of 85 may be outboard, or a combination of outboard and logic elements and dynamic OJFET shift registers as illustrated in FIG. 6. Programs residing in an outboard computer 87 supply the input data to the array 81, and also provide instructions to the control 85. The outboard computer and program, and the read/write/erase logic control cooperate so that the array 81 either emits or senses radiation. An outboard display 86 makes visible the output of array 81 from array input/output data device 84, as well as the programs and settings from 87 to 84, 85 and 86.

While the foregoing disclosure is directed toward the preferred embodiments of the invention, the scope of the invention is defined by the claims, which follow.

1. A device functional to X-ray and EUV radiation, comprising:
(a) a polyethylene semiconductor material;
(b) a true ohmic injection contact contacting said polyethylene semiconductor material on a first edge of said polyethylene semiconductor material;
(c) a true ohmic drain contacting said polyethylene semiconductor material on an opposing edge of said polyethylene semiconductor material;
(d) a surround gate p-type semiconductor contacting said polyethylene semiconductor material between said injection contact and said drain; and
(e) a gate interconnect metal contacting said polyethylene semiconductor material and said surround gate.

2. The device of claim 1, wherein said device functionally responds by sensing X-ray or EUV radiation.

3. The device of claim 1, wherein said device functionally responds by emitting X-ray or EUV radiation.

4. The device of claim 1, wherein said device is designed to be functionally responsive to a specific wavelength by doping and copolymerization of said polyethylene semiconductor material

5. The device of claim 1, wherein said device is fabricated by printing said polyethylene semiconductor material and said surround gate and said true ohmic injection contact and said interconnect metal and said true ohmic drain in a pattern and sequence required to produce cooperative elements of said device.

6. The device of claim 1, further comprising polymer encapsulating material which is designed in material and thickness to allow both transmission and reception of said X-ray and EUV radiation at a design center wavelength, and to protect said polyethylene semiconductor material and said surround gate and said interconnect metal and said true-ohmic injection contact and said true ohmic drain from the operating conditions and environment.

7. The device of claim 1, wherein:
(a) said polyethylene semiconductor material and said interconnect metal and said true-ohmic injector contact and said true ohmic drain and said surround gate are formed into fibers; and
(b) said fibers are organized in a warp and a woof of a weaving loom and are woven thereby forming a weave to fabricate said device.

8. The device of claim 1, wherein said device is fabricated on a radiation adsorbent substrate opposite an emission and sensing face for said X-ray and EUV radiation.

9. The device of claim 1, wherein said polyethylene semiconductor material has:
(a) n-type conductivity;
(b) a band gap of about 8.8 eV;
(c) a negative electron affinity of about 1.2 eV; and
(d) functionality to X-ray and EUV radiation with wavelength about λ=140 nm to λ=100 nm.

10. A method for fabricating a device functional to X-ray or EUV radiation, comprising the steps of:
(a) providing a polyethylene semiconductor material;
(b) contacting said polyethylene semiconductor material on a first edge with a true ohmic injection contact;
(c) contacting said polyethylene semiconductor material on an opposing with a true ohmic drain;
(d) contacting said polyethylene semiconductor material between said injection contact and said drain with a surround gate p-type semiconductor; and
(e) contacting said polyethylene semiconductor material and said surround gate with a gate interconnect metal.

11. The method of claim 10, comprising the additional step of doping and copolymerization said polyethylene semiconductor material so that said device is functional to said EUV and X-radiation at a specific wavelength.

12. The method of claim 10, wherein said device is used to sense X-ray or EUV radiation.

13. The method of claim 10, wherein said device is used to emit X-ray or EUV radiation.

14. The method of claim 10, comprising the additional step of fabricating said device by printing elements comprising said device.

15. The method of claim 10, comprising the additional steps of:
(a) forming fibers of materials which form elements of said device; and
(b) weaving said fibers to fabricate said device.

16. The method of claim 10, comprising the additional step of fabricating said device on a radiation adsorbent substrate opposite an emission and sensing face for said X-ray and EUV radiation

17. An apparatus functionally responsive to X-ray or EUV radiation, comprising:
(a) a M×N array of OJFET elements;
(b) an N row address logic cooperating with elements within N rows of said array;
(c) an M row address logic cooperating with elements within M rows of said array;
(d) read/write/address logic control functionally connected to said M row and said N row address logics;
(e) an outboard display functionally connected to said array; and
(f) an outboard computer and program functionally connected to said read/write/address logic control and said outboard display.

18. The apparatus of claim 17, wherein said outboard computer and program, and said read/write/erase logic control function so that said array emits X-ray or EUV radiation.

19. The apparatus of claim 17, wherein said outboard computer and program, and said read/write/erase logic control function so that said array senses X-ray or EUV radiation impinging thereon.

20. The apparatus of claim 17, wherein said OJFET elements are fabricated by printing components of said OJFET elements in a pattern and sequence required to produce required functional connections of said components.

21. The apparatus of claim 20, wherein said an N row address logic and said M row address logic and said read/write/address logic control are integrally fabricated with said OJFET elements by printing.

22. The apparatus of claim 17, wherein materials used to fabricate said OJFET elements are formed into fibers and said fibers are organized in a warp and a woof of a weaving loom and are woven thereby forming a said array of OJFET elements.

23. The apparatus of claim 22, wherein said an N row address logic and said M row address logic and said read/write/address logic control are integrally fabricated with said OJFET elements by weaving.

24. The apparatus of claim 17, wherein each said OJFET element comprises:
(a) a polyethylene semiconductor material;
(b) a true ohmic injection contact contacting said polyethylene semiconductor material on a first edge of said polyethylene semiconductor material;
(c) a true ohmic drain contacting said polyethylene semiconductor material on an opposing edge of said polyethylene semiconductor material;
(d) a surround gate p-type semiconductor contacting said polyethylene semiconductor material between said injection contact and said drain; and
(e) a gate interconnect metal contacting said polyethylene semiconductor material and said surround gate.

25. A method of operating an apparatus functionally responsive to X-ray or EUV radiation, comprising:
(a) providing a M×N array of OJFET elements;
(b) operationally addressing said OJFET elements in said N row with an N row address logic;
(c) operationally addressing said OJFET elements in said M row with an M row address logic; and
(d) controlling functionality of said operationally addressed OJFET elements with an outboard computer and program through a read/write/address logic control connected to said array.

26. The method of claim 25, comprising the additional step of setting said outboard computer and program and said read/write/erase logic control cooperate so that said array emits X-ray or EUV radiation.

27. The method of claim 25, comprising the additional step of setting said outboard computer and program and said read/write/erase logic control cooperate so that said array senses X-ray or EUV radiation impinging thereon.

28. The method of claim 25, wherein said OJFET elements are fabricated by printing components of said OJFET elements a pattern and sequence required to produce functional connections of said components of said device.

29. The method of claim 28, comprising the additional step of integrally fabricating said an N row address logic and said M row address logic and said read/write/address logic with said OJFET elements by printing.

30. The method of claim 25, wherein materials used to fabricate said OJFET elements are formed into fibers and said fibers are organized in a warp and a woof of a weaving loom and are woven thereby forming a said array of OJFET elements.

31. The method of claim 30, comprising the additional step of integrally fabricating said an N row address logic and said M row address logic and said read/write/address logic control with said OJFET elements by weaving.

32. The method of claim 25, wherein OJFET elements are fabricated by
(a) providing a polyethylene semiconductor material;
(b) contacting said polyethylene semiconductor material on a first edge with a true ohmic injection contact;
(c) contacting said polyethylene semiconductor material on an opposing with a true ohmic drain;
(d) contacting said polyethylene semiconductor material between said injection contact and said drain contact with a surround gate p-type semiconductor; and
(e) contacting said polyethylene semiconductor material and said surround gate with a gate interconnect metal.
